(19) United States
(12) Patent Application Publication
(10) Pub. No.: US 2025/0171892 A1
(43) Pub. Date: May 29, 2025

(54) APPARATUSES AND METHODS FOR FILLING A GAP

(71) Applicant: ASM IP Holding B.V., Almere (NL)

(72) Inventors: Ranjit Borude, Tokyo (JP); Makoto Igarashi, Tokyo (JP); Hideaki Fukuda, Tokyo (JP); Viljami Pore, Helsinki (FI); Ville Liimatainen, Espoo (FI)

(21) Appl. No.: 18/959,829

(22) Filed: Nov. 26, 2024

Related U.S. Application Data
(60) Provisional application No. 63/603,671, filed on Nov. 29, 2023.

(51) Int. Cl. C23C 16/04; C23C 16/24; C23C 16/56

(52) U.S. Cl. CPC C23C 16/045; C23C 16/24; C23C 16/56

(57) ABSTRACT

A method and system for depositing silicon using a multiple-chamber reactor are disclosed. An exemplary method includes performing one or more deposition cycles and performing a vacuum ultraviolet radiation, and an optional anneal.

### CROSS-REFERENCE TO RELATED APPLICATIONS

This application claims priority to and the benefit of U.S. Provisional Application No. 63/603,671, filed Nov. 29, 2023, the entirety of which is incorporated by reference herein.

### FIELD OF INVENTION

The present disclosure generally relates to methods and apparatuses for semiconductor manufacturing.

### BACKGROUND OF THE DISCLOSURE

The miniaturization of semiconductor devices has improved the speed and density of integrated circuits. However, owing to shrinking geometries, filling gaps in substrates for shallow trench isolation, inter-metal and passivation layers with high-quality material fully void-free has become difficult.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods that can be used to fill a gap on a substrate. While the ways in which various embodiments of the present disclosure address drawbacks of prior methods are discussed in more detail below, in general, various embodiments of the disclosure provide improved reactor systems for filling a gap on a substrate and improved methods of filling a gap on a substrate. As explained in more detail below, use of multiple-chamber reactor systems and corresponding methods can reduce contamination associated with deposition of material, can provide deposited material with desired properties, and/or can increase throughput associated with deposition of material with desired properties and/or features.

In accordance with at least one embodiment of the disclosure, a multiple chamber reactor system comprises a first reaction chamber configured to deposit a layer comprising silicon into a gap on a substrate to form a deposited layer. The system further comprises a second reaction chamber configured to expose the deposited layer to vacuum ultraviolet radiation to form an exposed layer; and a controller. The controller is configured to provide the substrate comprising at least one gap within the first reaction chamber; perform a deposition cycle in the first reaction chamber; move the substrate from the first reaction chamber to the second reaction chamber; and perform an exposure process in the second reaction chamber.

In some embodiments, the controller is configured to execute a plurality of the deposition cycles in the first reaction chamber prior to moving the substrate to the second reaction chamber.

The multiple-chamber reactor system can further include a third reaction chamber configured to deposit an additional layer comprising silicon on a surface of the exposed layer and a fourth reaction chamber configured to treat the exposed layer. In such cases, the controller can be configured to move the substrate from the first reaction chamber to the second reaction chamber, from the second reaction chamber to the third reaction chamber, and from the third reaction chamber to the fourth reaction chamber to form a layer comprising silicon and oxygen. Alternatively, the controller can be configured to move substrates between the first and second reaction chambers and/or between the third and fourth reaction chambers to repeat deposition and treatment/exposure steps as described herein. Two or more (e.g., four) reaction chambers can form part of a process module.

In accordance with further exemplary embodiments of the disclosure, a method for depositing a layer comprising silicon and oxygen, the method comprises providing a substrate within the first reaction chamber, wherein the substrate comprises at least one gap; depositing a layer comprising silicon into a gap on the substrate within the first reaction chamber to form a deposited layer; exposing the deposited layer in a second reaction chamber to vacuum ultraviolet radiation to form an exposed layer comprising silicon and oxygen. The first reaction chamber and the second reaction chamber can form part of a module.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a multiple-chamber reactor system in accordance with at least one embodiment of the disclosure.

FIG. 2 illustrates a method in accordance with at least one embodiment of the disclosure.

FIG. 3 illustrates a reaction chamber suitable for use in accordance with embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Exemplary embodiments of the disclosure provide improved systems and methods for filling a gap on a substrate. Exemplary systems and methods can be used to fill a gap with a material comprising silicon and oxygen via a conversion reaction. Further, exemplary systems and methods can be used to deposit, expose and optionally treat layers comprising silicon and nitrogen or silicon and oxygen in a single process module, e.g., without exposing a substrate to ambient conditions. Thus, any contamination of the surface that may otherwise result from performing a pre-deposition treatment and/or exposure to ambient conditions can be mitigated or avoided.

In this disclosure, a gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas.

In some cases, the term precursor can refer to a compound that participates in a chemical reaction that produces another compound, and particularly to a compound that constitutes a film matrix or a main skeleton of a film. In some cases, the term reactant can be used interchangeably with the term precursor. The term inert gas can refer to a gas that does not take part in a chemical reaction and/or does not become a part of a film matrix to an appreciable extent. Exemplary inert gases include He, Ar, H₂, N₂ (e.g., when not activated by a plasma) and any combination thereof.

As used herein, the term substrate can refer to any underlying material or materials that may be used to form, or upon which, a device, a circuit, or a film may be formed. A substrate can include a bulk material, such as silicon (e.g., single-crystal silicon) and can include one or more layers overlying the bulk material. Further, the substrate can include various topologies, such as recesses, lines, and the like formed within or on at least a portion of a layer of the substrate. By way of example, the substrate can include a surface comprising a first material and a second material, as described in more detail below.

As used herein, the term “film and/or layer can refer to any continuous or non-continuous structures and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

As used herein, the term cyclical deposition may refer to a process that includes sequential introduction of precursors and/or reactants into a reaction chamber and/or sequential plasma power pulses to deposit a layer over a substrate. Cyclical deposition processes include processing techniques, such as atomic layer deposition (ALD), cyclical chemical vapor deposition (CCVD), and plasma-enhanced ALD and CCVD.

As used herein, the term cyclical chemical vapor deposition may refer to any process wherein a substrate is sequentially exposed to two or more volatile precursors/reactants, which react and/or decompose on a substrate to produce a desired deposition.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

A layer comprising silicon and nitrogen can comprise, consist essentially of, or consist of silicon nitride material. Layers consisting of silicon nitride can include an acceptable amount of impurities, such as carbon, chlorine or other halogen, and/or hydrogen, which may originate from one or more precursors used to deposit the silicon nitride layers. As used herein, SiN or silicon nitride refers to a compound that includes silicon and nitrogen. SiN can be represented as SiNₓ, where x varies from, for example, about 0.5 to about 2.0, where some Si-N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary. Silicon nitride can include silicon carbon nitride (SiCN), which includes silicon carbon and nitrogen.

A layer comprising silicon and oxide can comprise, consist essentially of, or consist of silicon oxide material. Layers consisting of silicon oxide can include an acceptable amount of impurities, such as carbon, chlorine or other halogen, and/or hydrogen, which may originate from one or more precursors used to deposit the silicon nitride layers. As used herein, SiOₓ or silicon oxide refers to a compound that includes silicon and oxygen. SiO can be represented as SiOₓ, where x varies from, for example, about 0.5 to about 2.0, where some Si—O bonds are formed. In some cases, x may vary from about 0.9 to about 1.7, from about 1.0 to about 1.5, or from about 1.2 to about 1.4. In some embodiments, silicon oxide is formed where Si has an oxidation state of +IV and the amount of oxide in the material may vary.

In some embodiments, a layer comprising silicon and nitrogen further comprises carbon. These films comprise, consists essentially of, or consist of silicon carbon nitride material. Layers consisting of silicon carbon nitride can include an acceptable amount of impurities, such as chloride or other halogen, and/or hydrogen, which may originate from one or more precursors used to deposit the silicon carbon nitride layers. As used herein, SiCN or silicon carbon nitride refers to a compound that includes silicon, carbon and nitrogen.

As used herein, a structure can include a substrate as described herein. Structures can include one or more layers overlying the substrate, such as one or more layers formed according to a method as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including, constituted by and having” can refer independently to typically or broadly comprising, comprising, consisting essentially of, or consisting of in some embodiments. It shall be understood that when a composition, method, device, or the like is said to comprise certain features, it means that it includes those features, and that it does not necessarily exclude the presence of other features, as long as they do not render the claim unworkable. This notwithstanding, the term comprises or includes or has includes the meaning of consists of, i.e., the case when the composition, method, device, or the like in question only includes the features, components, and/or steps that are listed, and does not contain any other features, components, steps, and the like, and includes consisting essentially of.

In this disclosure, any defined meanings do not necessarily exclude ordinary and customary meanings in some embodiments.

In accordance with at least one embodiment of the disclosure, a multiple chamber reactor system comprises a first reaction chamber configured to deposit a layer comprising silicon into a gap on a substrate to form a deposited layer. The system further comprises a second reaction chamber configured to expose the deposited layer to vacuum ultraviolet radiation to form an exposed layer; and a controller. The controller is configured to provide the substrate comprising at least one gap within the first reaction chamber; perform a deposition cycle in the first reaction chamber; move the substrate from the first reaction chamber to the second reaction chamber; and perform a conversion process in the second reaction chamber.

In accordance with examples of these embodiments, the controller is configured to execute a plurality of the deposition cycles in the first reaction chamber prior to moving the substrate to the second reaction chamber.

The multiple-chamber reactor system can further include a third reaction chamber configured to deposit additional layer comprising silicon on a surface of the exposed layer and a fourth reaction chamber configured to treat the exposed layer. In some embodiments, the controller can be configured to move the substrate from the first reaction chamber to the second reaction chamber, from the second reaction chamber to the fourth reaction chamber, and from the fourth reaction chamber to the third reaction chamber to form a layer comprising silicon and oxygen.

In some embodiments, the controller can be configured to move the substrate from the first reaction chamber to the second reaction chamber, from the second reaction chamber to the third reaction chamber, and from the third reaction chamber to the fourth reaction chamber to form a layer comprising silicon and oxygen. Alternatively, the controller can be configured to move substrates between the first and second reaction chambers and/or between the third and fourth reaction chambers to repeat deposition and treatment/exposure steps as described herein. Two or more (e.g., four) reaction chambers can form part of a process module. The order of the reaction chambers in which the controller is configured to move the substrate can vary and can be any other order which is not specifically listed in this disclosure.

In accordance with further exemplary embodiments of the disclosure, a method for depositing a layer comprising silicon and oxygen, the method comprises providing a substrate within the first reaction chamber, wherein the substrate comprises at least one gap; depositing a layer comprising silicon into a gap on the substrate within the first reaction chamber to form a deposited layer; exposing the deposited layer in a second reaction chamber to vacuum ultraviolet radiation to form an exposed layer comprising silicon and oxygen. In some embodiments, the first reaction chamber and the second reaction chamber can form part of a module.

In some embodiments of the deposition step of the current invention, a silicon-containing precursor is provided into the reaction chamber. In some embodiments, the deposited layer comprises silicon nitride. In some embodiments, the deposited layer comprises silicon oxide. Additionally a plasma pulse is provided that comprises exposing the substrate to a plasma treatment. The plasma treatment allows the deposited film to polymerize and convert into a flowable film. This flowable film will then fill the trench on the substrate without formation of any voids. The plasma treatment comprises generating a plasma using a plasma gas. The plasma gas comprises at least nitrogen gas, and optionally one or more noble gases. In some embodiments, the noble gas is argon or helium.

In some embodiments, the silicon-containing precursor can be any precursor comprising silicon. In some embodiments, the silicon-containing precursor is selected from the group consisting of N-(diethylaminosilyl)-N-ethylethanamine and N,N′-disilylsilanediamine.

In some embodiments, the deposition step further comprises providing a carbon-containing precursor into the reaction chamber. In some embodiments, the deposited layer comprises silicon carbon nitride. In some embodiments, the carbon-containing precursor is selected from the group consisting of hexamethyldisilazane, hexamethyltrisilazane, tetramethyldivinyldisilazane, tetramethyldisilazane and tetraisocyanatosilane.

In accordance with some exemplary embodiments of the vacuum ultraviolet radiation step of the current invention, the deposited film is exposed to vacuum ultraviolet radiation. In the vacuum ultraviolet chamber, oxygen gas is fed simultaneously or at least overlapping the radiation. In the presence of the ultraviolet radiation, the molecular oxygen will undergo dissociation to form ozone and atomic oxygen. These will then react with the layer deposited in the deposition chamber. In some embodiments, a deposited silicon nitride layer is converted into a silicon oxide layer. In some embodiments, a deposited silicon carbon nitride layer is converted into a silicon oxycarbon nitride layer.

In some embodiments, the properties of the silicon oxide layer are modified by the ultraviolet radiation. In some embodiments, the wet etch rate ratio is lowered. This decrease may be explained by the reaction between the reaction between the atomic oxygen from the oxygen fed into the ultraviolet radiation chamber and hydrogen bonded to the silicon oxide layer. As the hydrogen and atomic oxygen react, they evaporate from the surface of the layer as water. The decreased amount of hydrogen in the silicon oxide layer then improves the wet etch rate ratio of the layer. In some embodiments, the process time is decreased by using the process according to the current description, compared to a traditional inhibitor process. This leads to a higher throughput; in other words, more process wafers can be handled within a certain time limit when compared to a traditional inhibitor process which is done in one process chamber.

In some embodiments, the ultraviolet radiation can cure any possible seams that are formed during the step of depositing a layer comprising silicon into at least one gap on a substrate. In other words, the seams can be mended or made non-existent by using the ultraviolet radiation. The ultraviolet radiation activates the deposited material in the seam to form new chemical bonds to bond the seam. In some embodiments, a gas is provided into the reaction chamber simultaneously to the ultraviolet radiation. The ultraviolet radiation activates the gas to form reactive species to react inside the seam forming new chemical bonds within the seam. In some embodiments, the gas provided into the reaction chamber is selected from the list consisting of: NH3, silane, alkoxysilane, alkylaminosilane, titanium alkoxide, titanium alkylamine, titanium tetrachloride and trimethyl aluminum.

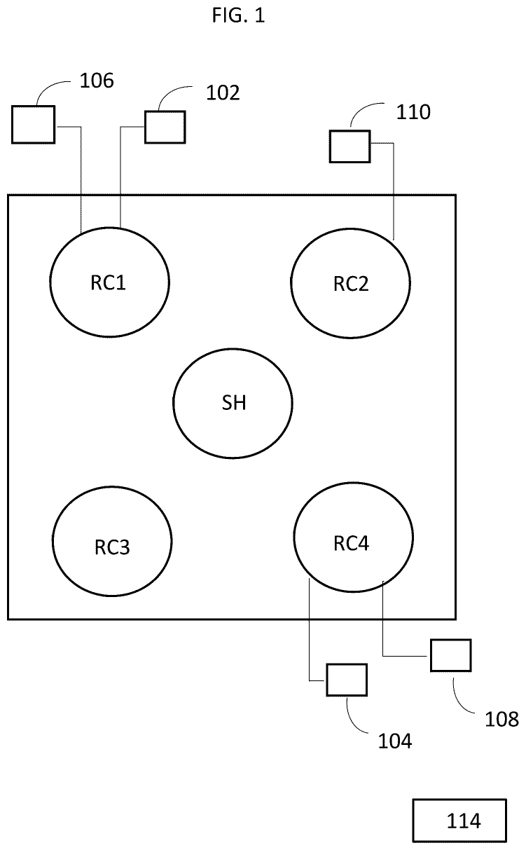

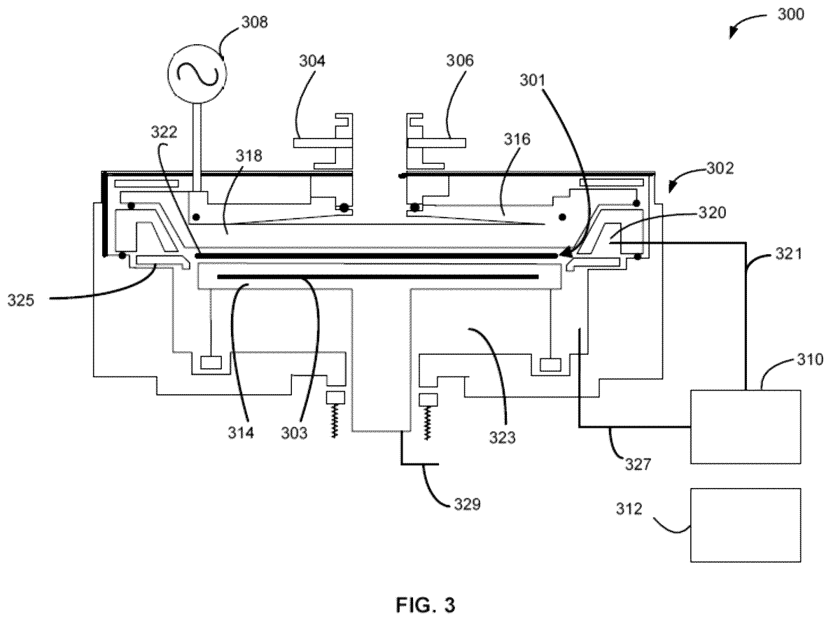

Turning now to the figures, FIG. 1 illustrates a multiple-chamber reactor system 100 in accordance with embodiments of the disclosure. In the illustrated embodiment, multiple-chamber reactor system 100 includes a first reaction chamber RC1, a second reaction chamber RC2, a third reaction chamber RC3, and a fourth reaction chamber RC4. A configuration of RC1-RC4 can vary according to desired processes. An exemplary reaction chamber suitable for use as one or more of RC1-RC4 is described in more detail below in connection with FIG. 3.

In accordance with embodiments of the disclosure, at least one of RC1-RC4 is configured to deposit a silicon-containing film on a surface of a substrate to form a deposited layer comprising silicon oxide. By way of example, RC1 and RC3 can be configured to deposit a silicon-containing film on a surface of the substrate.

In accordance with further embodiments of the disclosure, at least one of RC1-RC4 is configured to expose the deposited layer to vacuum ultraviolet radiation. For example, RC2 and/or RC4 can be configured to treat the deposited silicon nitride.

In accordance with further embodiments of the disclosure, at least one of RC1-RC4 is configured to treat the exposed layer with thermal anneal. For example, RC2 and/or RC4 can be configured to treat the deposited silicon nitride.

Multiple-chamber reactor system 100 can also include a substrate handler SH configured to move substrates between two or more reaction chambers RC1-RC4. For example, substrate handler SH (and a controller 114) can be configured to move a substrate between RC1, RC2, RC3, and RC4 and optionally repeat. In these cases, the third reaction chamber RC3 can be configured to deposit additional silicon-containing layer on a surface of treated and/or exposed layer and RC4 can be configured to treat the silicon-containing layer. Additionally or alternatively, substrate handler SH (and controller 114) can move substrates between RC1 and RC2 and repeat and/or between RC3 and RC4 and repeat.

Multiple-chamber reactor system 100 can also include a silicon precursor source 102, 104 coupled to, for example, RC1 and/or RC3. Each silicon precursor source 102, 104 includes a vessel and a silicon precursor therein. Exemplary suitable silicon precursors are set forth above. Although separately illustrated, silicon precursor source 102, 104 can be a single precursor source.

Multiple-chamber reactor system 100 can also include a carbon-containing precursor source 106, 108 coupled to one or more reaction chambers RC1, RC4. Each carbon-containing precursor source 106, 108 includes a vessel and a carbon-containing precursor. Exemplary carbon-containing reactants as also set forth above.

Controller 114 can be configured to move substrates within multiple-chamber reactor system 100 and to effectuate deposition and treatment processes as described herein. For example, controller 114 can be configured to provide the substrate within the first reaction chamber, perform a deposition cycle in the first reaction chamber, move the substrate to the second reaction chamber, and perform an exposure process in the second reaction chamber. In a particular embodiment, controller 114 can be configured to perform a deposition cycle in the first reaction chamber, wherein the deposition cycle comprises pulsing a silicon precursor from silicon precursor source 102 to first reaction chamber RC1, providing the nitrogen-containing reactant from nitrogen-containing reactant source 106 to first reaction chamber RC1, and providing a deposition plasma power to form activated species from the nitrogen-containing reactant.

Additionally or alternatively, controller 114 can be configured to perform an exposure process in second reaction chamber RC2, wherein the exposure process comprises providing an oxygen-containing reactant from oxygen reactant source 110 to second reaction chamber RC2 and providing vacuum ultraviolet radiation to form activated species from the oxygen-containing reactant. Additionally or alternatively, controller 114 can be configured to perform an anneal process in third reaction chamber RC3, wherein the anneal process comprises heating the reaction chamber to a temperature over 400° C. In some embodiments, controller 114 is configured to execute a plurality of the deposition cycles (e.g., between about 1 and about 500 or between about 1 and 300 deposition cycles) in first reaction chamber RC1 prior to moving the substrate to second reaction chamber RC2. In some cases, the controller 114 is further configured to move the substrate from second reaction chamber RC2 to first reaction chamber RC1.

In accordance with further examples of the disclosure, controller 114 may further be configured to ramp up a flow of the oxygen-containing reactant after the substrate is within the second reaction chamber. Controller 114 can be further configured to ramp down the flow of the oxygen-containing reactant before the substrate is removed from the second reaction chamber. One or both of the ramp rates may be relatively constant.

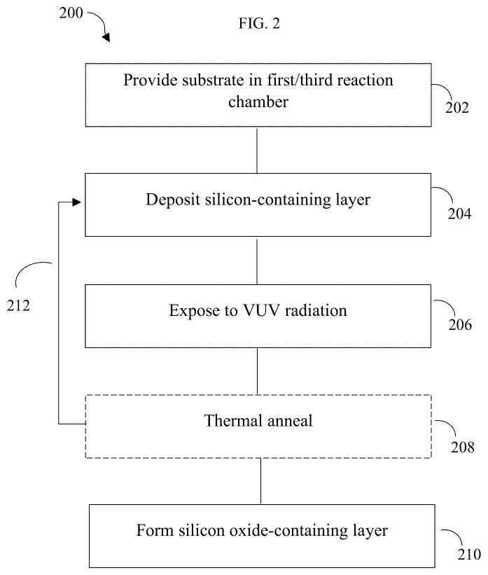

FIG. 2 illustrates a method 200 of depositing silicon oxide-containing layer in accordance with additional embodiments of the disclosure.

Method 200 includes the steps of providing a substrate within a reaction chamber (step 202), depositing silicon-containing layer (step 204), exposing the silicon-containing layer to vacuum ultraviolet (VUV) radiation (step 206), optionally treating the exposed layer with a thermal anneal step (step 208), to form a silicon oxide-containing layer (step 210).

During step 202, a substrate is provided into a reaction chamber of a reactor. The substrate comprises at least one gap. Optionally, a reactor including the reaction chamber can be provided with a heater to activate reactions by elevating the temperature of one or more of the substrate and/or the reactants/precursors.

During step 202, the substrate can be brought to a desired temperature and pressure for step 204. By way of examples, a temperature (e.g., of a substrate or a substrate support) within a reaction chamber can be between about 50° C. and about 200° C. or about 80° C. and about 150° C. A pressure within the reaction chamber can be about 0.5 to about 50 or about 1 to about 30 Torr.

During step 204, one or more deposition cycles are performed to deposit silicon-containing material on the surface of the substrate. In some cases, the deposited silicon-containing layer is flowable. In some embodiments, the deposition the process comprises providing a silicon-containing precursor. In some embodiments, the deposition process comprises providing a silicon-containing precursor, and a plasma pulse. In some embodiments, the deposition the process comprises providing a silicon-containing precursor, providing a second precursor, and a plasma pulse. In the embodiments containing the plasma pulse, the plasma polymerizes the deposited layer to make it flowable.

In one embodiment, the deposition cycle comprises: pulsing a silicon precursor from a silicon precursor source to the first reaction chamber; and providing a deposition plasma power to form activated species from a reactant to deposit a layer comprising silicon nitride. In one embodiment, the deposition cycle comprises: pulsing a silicon precursor from a silicon precursor source to the first reaction chamber; pulsing a carbon precursor from a carbon precursor source to the first reaction chamber; and providing a deposition plasma power to form activated species from a reactant to deposit a layer comprising silicon carbon nitride. In one embodiment, the deposition cycle comprises: pulsing a silicon precursor from a silicon precursor source to the first reaction chamber; and providing a deposition plasma power to form activated species from a reactant to deposit a layer comprising silicon oxide.

During step 204 a plasma power is provided for a plasma period to form activated species from the reactant gas. The deposition plasma power can have a frequency of between about 100 kHz and about 60 MHz and/or between about 12 MHz and about 14 MHz. The plasma power can have a power of between about 10 and about 2000 W or between about 100 and about 900 W or be about 30 W to about 500 W for a 300 mm diameter substrate or have similar power densities for substrates of different cross-sectional dimensions, and particularly for a CCP process. Power levels may be higher for an IPC process. A duration of step 204 can be between about 0.05 seconds and about 60 seconds or between about 0.5 seconds and about 30 seconds.

In some embodiments, a plurality of deposition cycles are performed before the substrate is moved to a second reaction chamber.

During step 206, the deposited layer is exposed to VUV radiation in a second reaction chamber. A flow of oxygen-containing reactant gas is fed into the second reaction chamber. In some embodiments, VUV radiation decomposes the oxygen into ozone and reactive oxygen species which then react with the surface of the deposited layer. In some embodiments, the reactive oxygen species can reach up a depth of about 120 nm inside the gap. In some embodiments, when the deposited layer comprising silicon and nitrogen is exposed to the VUV radiation, the exposure to VUV radiation converts the layer to a converted layer comprising silicon oxide. In some embodiment, the exposure to VUV radiation converts the layer comprising silicon carbon nitride to a converted layer comprising silicon oxycarbon nitride. In some embodiments, the ultraviolet radiation is provided by an excimer lamp. In some embodiments, the ultraviolet radiation source is a low-pressure mercury lamp. In some embodiments, the wavelength of the vacuum ultraviolet is 100-450 nm. In some embodiments, the wavelength of the vacuum ultraviolet is 172 nm. After the exposure step 206, in some embodiments, the substrate is moved to the third reaction chamber for an optional anneal step 208.

During optional step 208, the exposed layer is subjected to an anneal step. In some embodiments, the anneal step comprises a thermal anneal in which the substrate is subjected to a temperature between 400 and 600° C. In some embodiments, the substrate is subjected to a temperature of about 500° C., or about 550° C. A pressure within the reaction chamber during step 208 can be between about 1 Torr and about 30 Torr or between about 2.6 Torr and about 15 Torr.

The thermal anneal densifies the formed layer as it can reduce the number of Si-H bonds in the formed layer. Optionally, after the thermal anneal, the substrate can be moved to a fourth reaction chamber or back to the first reaction chamber to repeat the deposition of a silicon-containing layer 204.

Finally, during step 210, a silicon oxide containing-layer is formed. In some embodiments, the formed layer is silicon oxide. In some embodiments, the formed layer is silicon oxycarbon nitride.

Turning now to FIG. 3, a reactor system 300 in accordance with further embodiments of the disclosure is illustrated. Reactor system 300 can be used to perform one or more steps or substeps as described herein and/or to form one or more device structures or portions thereof as described herein.

Reactor system 300 includes a pair of electrically conductive flat-plate electrodes 314, 318 in parallel and facing each other in an interior 301 (reaction zone) of a reaction chamber 302. A plasma can be excited within reaction chamber 302 by applying, for example, plasma power from plasma power source(s) 308 to one electrode (e.g., electrode 318) and electrically grounding the other electrode (e.g., electrode 314). A temperature regulator 303 can be provided in a lower stage 314 (the lower electrode), and a temperature of a substrate 322 placed thereon can be kept at a desired temperature, such as the temperatures noted above. Electrode 318 can serve as a gas distribution device, such as a shower plate or showerhead. Precursor gases, reactant gases, and a carrier or inert gas, if any, or the like can be introduced into reaction chamber 302 using one or more gas lines (e.g., reactant gas line 304 and precursor gas line 306, respectively, coupled to a reactant source and a precursor source). For example, an inert gas and a reactant (e.g., as described above) can be introduced into reaction chamber 302 using line 304 and/or a precursor and a carrier gas (e.g., an inert gas as described above) can be introduced into the reaction chamber 302 using line 306. Although illustrated with two inlet gas lines 304, 306, reactor system 300 can include any suitable number of gas lines.

In reaction chamber 302, a circular duct 320 with an exhaust line 321 can be provided, through which gas in the interior 301 of the reaction chamber 302 can be exhausted to an exhaust source 310. Additionally, a transfer chamber 323 can be provided with a seal gas line 329 to introduce seal gas into the interior 301 of reaction chamber 302 via the interior (transfer zone) of transfer chamber 323, wherein a separation plate 325 for separating the reaction zone 301 and the transfer chamber 323 can be provided (a gate valve through which a substrate is transferred into or from transfer chamber 323 is omitted from this figure). Transfer chamber 323 can also be provided with an exhaust line 327 coupled to exhaust source 310. In some embodiments, continuous flow of a carrier gas to reaction chamber 302 can be accomplished using a flow-pass system (FPS).

Reactor system 300 can include one or more controller(s) 312 programmed or otherwise configured to cause one or more method steps as described herein to be conducted. Controller(s) 312 are coupled with the various power sources, heating systems, pumps, robotics and gas flow controllers, or valves of the reactor, as will be appreciated by the skilled artisan. By way of example, controller 312 can be configured to control gas flow of a precursor, a reactant, and an inert gas into at least one of the one or more reaction chambers to form a layer on a surface of a substrate. Controller 312 can be further configured to provide power to form a plasma, e.g., within reaction chamber 302. Controller 312 can be similarly configured to perform additional or alternative steps as described herein. By way of example, controller 312 can be configured to perform a step of treating the deposited material, etching, and/or curing.

Controller 312 can include electronic circuitry and software to selectively operate valves, manifolds, heaters, pumps and other components included in system 300. Such circuitry and components operate to introduce precursors, reactants, and purge gases from the respective sources. Controller 312 can control timing of gas pulse sequences, temperature of the substrate and/or reaction chamber, pressure within the reaction chamber, and various other operations to provide proper operation of the system 300.

Controller 312 can include control software to electrically or pneumatically control valves to control flow of precursors, reactants, and/or purge gases into and out of the reaction chamber 302. Controller 312 can include modules, such as a software or hardware component, e.g., a FPGA or ASIC, which performs certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 300, substrates, such as semiconductor wafers, are transferred from, e.g., a substrate handling area 323 to the reaction zone 301. Once substrate(s) are transferred to reaction zone 301, one or more gases, such as precursors, reactants, carrier gases, and/or purge gases, are introduced into reaction chamber 302.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A multiple-chamber reactor system comprising:
a first reaction chamber configured to deposit a layer comprising silicon into at least one gap on a substrate to form a deposited layer;
a second reaction chamber expose the deposited layer to vacuum ultraviolet radiation; and
a controller configured to:
provide the substrate comprising at least one gap within the first reaction chamber;
perform a deposition cycle in the first reaction chamber;
move the substrate from the first chamber to the second reaction chamber; and
perform an exposure process in the second reaction chamber.

2. The multiple-chamber reactor system according to claim 1, wherein the controller is configured to execute a plurality of the deposition cycles in the first reaction chamber prior to moving the substrate from the first chamber to the second reaction chamber.

3. The multiple-chamber reactor system according to claim 1, wherein the controller is further configured to move the substrate from the second reaction chamber to the first reaction chamber.

4. The multiple-chamber reactor system according to claim 1, further comprising a third reaction chamber to treat the converted layer, wherein the controller is configured to move the substrate from the first or second reaction chamber to the third reaction chamber; and perform an anneal treatment process in the third reaction chamber.

5. The multiple-chamber reactor system according to claim 1, wherein the deposition cycle comprises:
pulsing a silicon precursor from a silicon precursor source to the first reaction chamber; and
providing a deposition plasma power to form activated species from a reactant to deposit a layer comprising silicon nitride.

6. The multiple-chamber reactor system according to claim 1, wherein the deposition cycle comprises:
pulsing a silicon precursor from a silicon precursor source to the first reaction chamber;
pulsing a carbon precursor from a carbon precursor source to the first reaction chamber; and
providing a deposition plasma power to form activated species from a reactant to deposit a layer comprising silicon carbon nitride.

7. The multiple-chamber reactor system according to claim 1, wherein the deposition cycle comprises:
pulsing a silicon precursor from a silicon precursor source to the first reaction chamber; and
providing a deposition plasma power to form activated species from a reactant to deposit a layer comprising silicon oxide.

8. The multiple-chamber reactor system according t claim 5, wherein the exposure to vacuum ultraviolet radiation converts the layer comprising silicon nitride to a converted layer comprising silicon oxide.

9. The multiple-chamber reactor system according to claim 6, wherein the exposure to vacuum ultraviolet radiation converts the layer comprising silicon carbon nitride to a converted layer comprising silicon oxycarbon nitride.

10. The multiple-chamber reactor system according to claim 8, wherein the conversion process comprises oxidizing the deposited layer with vacuum ultraviolet induced ozone and reactive oxygen species.

11. The multiple-chamber reactor system according to claim 1, wherein the vacuum ultraviolet radiation is provided by an excimer lamp.

12. The multiple-chamber reactor system according to claim 11, where the ultraviolet light source is a low pressure mercury lamp.

13. The multiple-chamber reactor system according to claim 11, wherein the wavelength of the vacuum ultraviolet radiation is 100-450 nm.

14. The multiple-chamber reactor system according to claim 13, wherein the wavelength of the vacuum ultraviolet radiation is 172 nm.

15. The multiple-chamber reactor system according to claim 4, further comprising a fourth reaction chamber, wherein the controller is further configured to deposit an additional layer comprising silicon on the surface of the converted layer or the surface of the treated converted layer, and
wherein the controller is further configured to move the substrate from the first reaction chamber to the second reaction chamber, from the second reaction chamber to the third reaction chamber, and from the third reaction chamber to the fourth reaction chamber.

16. The multiple-chamber reactor system according to claim 1, wherein the controller is further configured to ramp up a flow of an oxygen-containing reactant after the substrate is within the second reaction chamber.

17. The multiple-chamber reactor system according to claim 17, wherein the controller is further configured to ramp down the flow of oxygen-containing reactant before the substrate is removed from the second reaction chamber.

18. The multiple-chamber reactor system according to claim 1, wherein the vacuum ultraviolet radiation cures any seams formed in the deposited layer.

19-34. (canceled)
